(19) United States
(12) Patent Application Publication
(10) Pub. No.: US 2026/0293166 A1
(43) Pub. Date: Sep. 24, 2026

(54) PACKAGE COMPRISING A CONFIGURABLE INDUCTOR

(71) Applicant: QUALCOMM Incorporated, San Diego, CA (US)

(72) Inventors: Je-Hsiung LAN, San Diego, CA (US); Nosun PARK, San Diego, CA (US); Jonghae KIM, San Diego, CA (US); Kai LIU, San Diego, CA (US)

(21) Appl. No.: 19/088,583

(22) Filed: Mar. 24, 2025

(51) Int. Cl. H10D 1/20; H01L 23/498; H01L 25/18; H10D 1/68

(52) U.S. Cl. CPC H10D 1/20; H10W 70/635; H10W 70/65; H10W 90/00; H10D 1/68

(57) ABSTRACT

A device comprising a plurality of via interconnects comprising a first plurality of via interconnects; a second plurality of via interconnects; and a third plurality of via interconnects; at least one switch device; an encapsulation layer at least partially encapsulating the plurality of via interconnects and the at least one switch device; a first metallization portion comprising a plurality of first metallization interconnects, wherein the plurality of first metallization interconnects are coupled to the plurality of via interconnects; a second metallization portion comprising a plurality of second metallization interconnects, wherein the plurality of second metallization interconnects are coupled to the plurality of via interconnects.

### FIELD

Various features relate to packages and integrated devices.

### BACKGROUND

A package may include a substrate and integrated devices. These components are coupled together to provide a package that may perform various electrical functions. There is an ongoing need to provide better performing packages, including providing better performing integrated devices. Moreover, there is also an ongoing need to reduce and/or minimize the overall size of the packages.

### SUMMARY

Various features relate to packages and integrated devices.

One example provides a device comprising a plurality of via interconnects comprising a first plurality of via interconnects; a second plurality of via interconnects; and a third plurality of via interconnects; at least one switch device; an encapsulation layer at least partially encapsulating the plurality of via interconnects and the at least one switch device; a first metallization portion comprising a plurality of first metallization interconnects, wherein the plurality of first metallization interconnects are coupled to the plurality of via interconnects; a second metallization portion comprising a plurality of second metallization interconnects, wherein the plurality of second metallization interconnects are coupled to the plurality of via interconnects.

### BRIEF DESCRIPTION OF THE DRAWINGS

Various features, nature and advantages may become apparent from the detailed description set forth below when taken in conjunction with the drawings in which like reference characters identify correspondingly throughout.

FIG. 1 illustrates an exemplary cross sectional profile view of a device comprising a configurable inductor.

FIG. 2 illustrates an exemplary view of a switch device and a configurable inductor.

FIG. 3 illustrates exemplary conceptual inductors and their corresponding magnetic flux.

FIG. 4 illustrates a table of various configurations of the switches and inductors.

FIG. 5 illustrates an exemplary cross sectional profile view of an integrated device.

FIG. 6 illustrates an exemplary cross sectional profile view of a device comprising a configurable inductor.

FIG. 7 illustrates an exemplary cross sectional profile view of a device comprising a configurable inductor.

FIGS. 8A-8E illustrate an exemplary sequence for fabricating a device comprising a configurable inductor.

FIG. 9 illustrates an exemplary flow chart of a method for fabricating a device comprising a configurable inductor.

FIG. 10 illustrates an exemplary sequence for fabricating a device comprising a configurable inductor.

FIGS. 11A-11B illustrate an exemplary sequence for fabricating a device comprising a configurable inductor.

FIG. 12 illustrates an exemplary flow chart of a method for fabricating a device comprising a configurable inductor.

FIG. 13 illustrates various electronic devices that may integrate a die, an electronic circuit, an integrated device, an integrated passive device (IPD), a passive component, a package, and/or a device package described herein.

### DETAILED DESCRIPTION

In the following description, specific details are given to provide a thorough understanding of the various aspects of the disclosure. However, it will be understood by one of ordinary skill in the art that the aspects may be practiced without these specific details. For example, circuits may be shown as block diagrams in order to avoid obscuring the aspects in unnecessary detail. In other instances, well-known circuits, structures and techniques may not be shown in detail in order not to obscure the aspects of the disclosure.

The present disclosure describes a device comprising a plurality of via interconnects comprising a first plurality of via interconnects; a second plurality of via interconnects; and a third plurality of via interconnects; at least one switch device; an encapsulation layer at least partially encapsulating the plurality of via interconnects and the at least one switch device; a first metallization portion comprising a plurality of first metallization interconnects, wherein the plurality of first metallization interconnects are coupled to the plurality of via interconnects; a second metallization portion comprising a plurality of second metallization interconnects, wherein the plurality of second metallization interconnects are coupled to the plurality of via interconnects. In some implementations, the at least one switch device may be used to precisely tune and/or configure the inductance of an inductor in the device, to optimize the inductance that is provided in the power distribution network of the device, which helps provide a device with improved performance. The inductance of the inductor(s) may be tuned and/or configured in real time, as the device is/are operating. Thus, the inductance of the inductor(s) may be changed in real time with changing electrical conditions in the device.

### Exemplary Device Comprising a Configurable Inductor

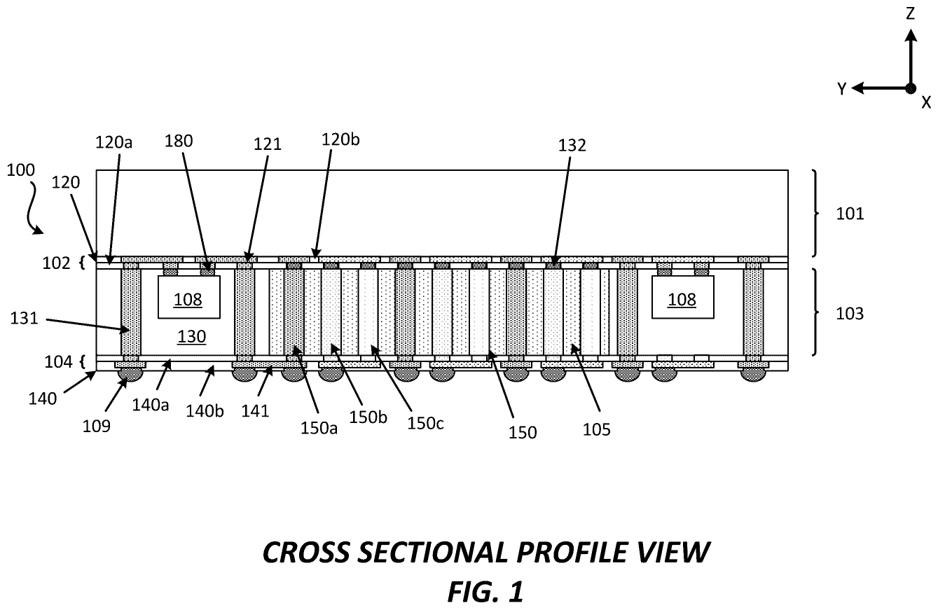

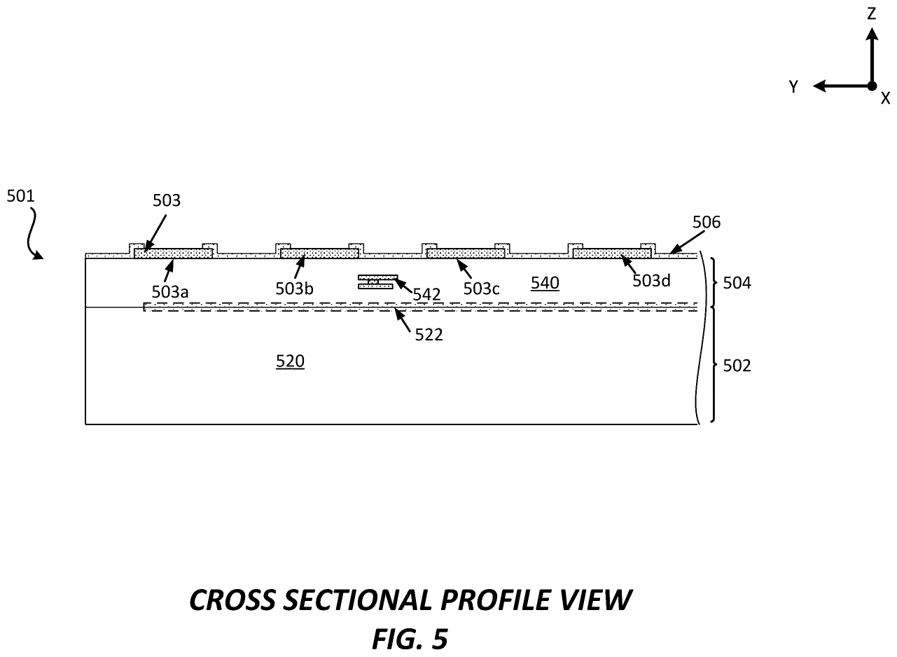

FIG. 1 illustrates a package 100 that includes an integrated device 101, a metallization portion 102, an encapsulated portion 103 and a metallization portion 104. The metallization portion 102 is coupled to the integrated device 101. The metallization portion 102 may be considered part of the integrated device 101. The encapsulated portion 103 is coupled to the metallization portion 102 and the metallization portion 104. The encapsulated portion 103 is located between the metallization portion 102 and the metallization portion 104. In some implementations, the metallization portion 102 may be a first metallization portion and the metallization portion 104 may be a second metallization portion. In some implementations, the metallization portion 104 may be a first metallization portion and the metallization portion 102 may be a second metallization portion. A more detailed example of the integrated device 101 is illustrated and described below in at least FIG. 5.

The metallization portion 102 includes at least one dielectric layer 120 and a plurality of metallization interconnects 121. The at least one dielectric layer 120 may include a dielectric layer 120a and a dielectric layer 120b. The at least one dielectric layer 120 may include polyimide. The metallization portion 104 includes at least one dielectric layer 140 and a plurality of metallization interconnects 141. The at least one dielectric layer 140 may include a dielectric layer 140a and a dielectric layer 140b. The at least one dielectric layer 140 may include polyimide. A plurality of solder interconnects 109 may be coupled to the metallization portion 104. The plurality of solder interconnects 109 may be coupled to the plurality of metallization interconnects 141 of the metallization portion 104. A metallization portion may include a redistribution portion. A plurality of metallization interconnects may include a plurality of redistribution interconnects.

As will be further described below, some of the interconnects in the package 100 are configured to operate as inductors. These inductors are used together to provide a precise inductance for a power distribution network of the package 100 and/or the integrated device 101, which helps provide a package and/or an integrated device with improved performance.

The encapsulated portion 103 may include a plurality of via interconnects 131, a plurality of via interconnects 150, at least one switch device 108, a magnetic layer 105 and an encapsulation layer 130. The magnetic layer 105 may at least partially encapsulate the plurality of via interconnects 150. The encapsulation layer 130 may at least partially encapsulate the plurality of via interconnects 131, the at least one switch device 108, the magnetic layer 105 and/or the plurality of via interconnects 150. In some implementations, the plurality of via interconnects 150 may be coupled to the metallization portion 102 through a plurality of solder interconnects 132. In some implementations, the at least one switch device108 may be coupled to the plurality of metallization interconnects 121 of the metallization portion 102 through a plurality of solder interconnects 180.

The plurality of via interconnects 150 may include a plurality of via interconnects 150a (e.g., first plurality of via interconnects), a plurality of via interconnects 150b (e.g., second plurality of via interconnects) and a plurality of via interconnects 150c (e.g., third plurality of via interconnects). The plurality of via interconnects 150a may be configured to be part of a first inductor. The plurality of via interconnects 150b may be configured to be part of a second inductor. The plurality of via interconnects 150c may be configured to be part of a third inductor. The magnetic layer 105 may be configured to at least partially encapsulate the plurality of via interconnects 150a, the plurality of via interconnects 150b and/or the plurality of via interconnects 150c. In some implementations, the magnetic layer 105 may be optional.

The magnetic layer 105 may include one or more magnetic layers. The magnetic layer 105 includes an insulating layer, a dielectric layer and/or a non-electrical conducting material (e.g., material that does not electrically conduct). The magnetic layer 105 may be both a dielectric material and a magnetic material. Thus, the magnetic layer 105 may have both dielectric properties and magnetic properties. The magnetic layer 105 may include one or more materials. The magnetic layer 105 has a permeability value that is greater than 1 (e.g., about 10 or greater, range of 6-12). The magnetic layer 105 may have different permeability values at different frequencies. In some implementations, the permeability value of a magnetic material and/or a magnetic layer, as described in the disclosure is a relative permeability value that is defined as a ratio of the permeability of a material to the permeability of free space or a non-magnetic material with permeability of 1.0 or greater, such as a general package electronic molding compound (EMC). Thus, the permeability values that are described for the magnetic materials and/or magnetic layers that are illustrated and/or described in the disclosure may represent a relative permeability value that is relative to a defined permeability value (e.g., reference permeability value) of free space. In some implementations, free space may be defined to have a defined permeability value of μ₀=4π×10⁻⁷ H/m (Henry per meter). A material that has a relative permeability value that is greater than 1 may be considered to be a magnetic material. Similarly, a material layer that has a relative permeability value that is greater than 1 may be considered to be a magnetic layer. The magnetic layer 105 may include a magnetic loss tangent value that is in a range of about 0.01-0.04. For example, the at least one magnetic layer may include a magnetic loss tangent value that is in a range of about 0.01-0.04 for frequencies up to 100 MHz. The magnetic layer 105 may include various magnetic materials. For example, the at least one magnetic layer 105 may include Ajinomoto Magnetic Film (AMF). The magnetic layer 105 is configured to improve the inductance and/or quality factor of an inductor that is located in and/or surrounded by the magnetic layer 105. With improved inductor performance, smaller and more compact inductors may be formed in the integrated device and/or the package.

In some implementations, some metallization interconnects from the metallization portion 102, some via interconnects from the plurality of via interconnects 150, and/or some metallization interconnects from the metallization portion 104 may be configured to operate as one or more inductors.

In some implementations, a first inductor of the package 100 may be defined by (i) a first plurality of metallization interconnects from the plurality of metallization interconnects 121 of the metallization portion 102, (ii) a first plurality of via interconnects (e.g., 150a) from the plurality of via interconnects 150 and (i) a first plurality of metallization interconnects from the plurality of metallization interconnects 141 of the metallization portion 104.

In some implementations, a second inductor of the package 100 may be defined by (i) a second plurality of metallization interconnects from the plurality of metallization interconnects 121 of the metallization portion 102, (ii) a second plurality of via interconnects (e.g., 150b) from the plurality of via interconnects 150 and (i) a second plurality of metallization interconnects from the plurality of metallization interconnects 141 of the metallization portion 104.

In some implementations, a third inductor of the package 100 may be defined by (i) a third plurality of metallization interconnects from the plurality of metallization interconnects 121 of the metallization portion 102, (ii) a third plurality of via interconnects (e.g., 150c) from the plurality of via interconnects 150 and (i) a third plurality of metallization interconnects from the plurality of metallization interconnects 141 of the metallization portion 104.

In some implementations, the second inductor and/or the third inductor may be electrically coupled to the at least one switch device 108. In some implementations, the second inductor and the third inductor may be electrically coupled to a switch device that includes two or more switches. In some implementations, the second inductor is electrically coupled to a first switch (e.g., first switch device) and the third inductor is electrically coupled to a second switch (e.g., second switch device). The at least one switch device 108 may be coupled to the metallization portion 102 through the plurality of solder interconnects 180. The at least one switch device 108 may be configured to be electrically coupled to the second inductor and/or the third inductor through the plurality of solder interconnects 180.

The first inductor may be a primary inductor. The first inductor may be configured to be electrically coupled to power and/or a power distribution network. The first inductor may be configured to be electrically coupled to the integrated device 101. The integrated device 101 may be configured as a power management integrated circuit (PMIC). The second inductor may be configured to change (e.g., increase) the inductance of the first inductor. The third inductor may be configured to change (e.g., decrease) the inductance of the first inductor. Thus, the second inductor and/or the third inductor are configured to precisely tune and/or configure the inductance of the first inductor to optimize the inductance that is provided in the power distribution network of the package 100 and/or the integrated device 101, which helps provide a package and/or an integrated device with improved performance. The inductance of the inductor(s) may be tuned and/or configured in real time, as the package and/or the integrated device is/are operating. Thus, the inductance of the inductor(s) may be changed in real time with changing electrical conditions in the package and/or the integrated device.

In some implementations, the at least one switch device 108 is configured to turn on and off the second inductor and/or the third inductor. The at least one switch device 108 may be controlled by the integrated device 101. However, different implementations may use different integrated devices to control the at least one switch device 108. For example, the at least one switch device 108 may be controlled by another integrated device (not shown) that is different from the integrated device 101.

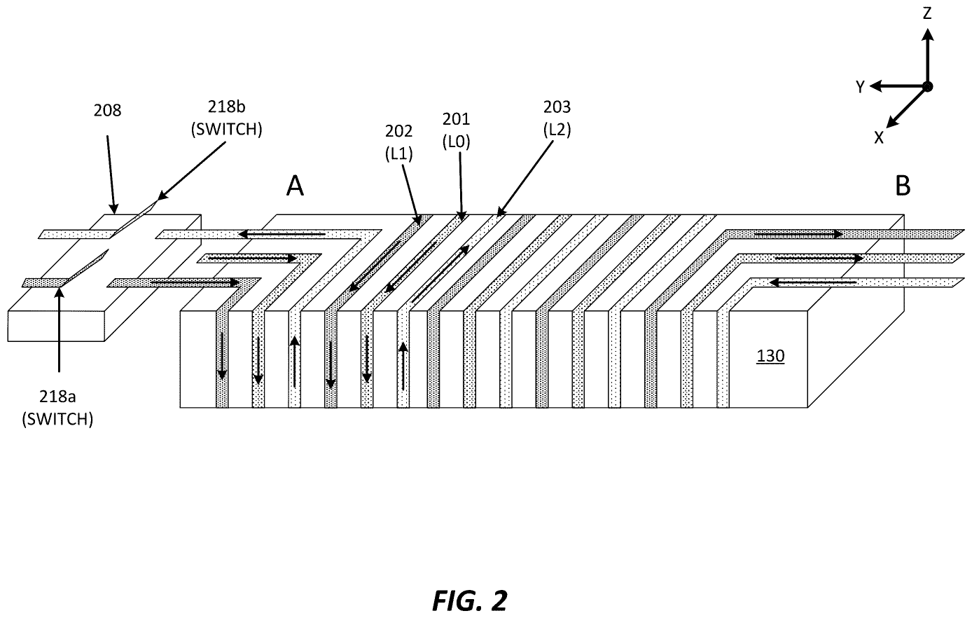

FIG. 2 illustrates a conceptual illustration of the inductors and the at least one switch device of FIG. 1. FIG. 2 illustrates the encapsulation layer 130, a first inductor 201, a second inductor 202, a third inductor 203 and a switch device 208. For purposes of simplification and clarity, not all of the components of the metallization portion 102, the metallization portion 104 and the magnetic layer 105 are shown. In some implementations, the vertical portions (along Z direction) of the first inductor 201, the second inductor 202 and/or the third inductor 203 may be represented by at least via interconnects from the plurality of via interconnects 150. In some implementations, the planar portions (along X-Y plane) of the first inductor 201, the second inductor 202 and/or the third inductor 203 may be represented by at least metallization interconnects from the plurality of metallization interconnects 121 of the metallization portion 102 and/or metallization interconnects from the plurality of metallization interconnects 141 of the metallization portion 104.

In some implementations, the first inductor 201 of the package 100 may be defined by (i) a first plurality of metallization interconnects from the plurality of metallization interconnects 121 of the metallization portion 102, (ii) a first plurality of via interconnects (e.g., 150a) from the plurality of via interconnects 150 and (i) a first plurality of metallization interconnects from the plurality of metallization interconnects 141 of the metallization portion 104. In some implementations, the first inductor 201 may further be defined by a first plurality of solder interconnects from the plurality of solder interconnects 132. The first plurality of solder interconnects from the plurality of solder interconnects 132 may be used to provide electrical paths between the first plurality of metallization interconnects from the plurality of metallization interconnects 121 of the metallization portion 102 and the first plurality of via interconnects (e.g., 150a) from the plurality of via interconnects 150. The first inductor 201 may be configured to be electrically coupled to an integrated device (e.g., 201).

In some implementations, the second inductor 202 of the package 100 may be defined by (i) a second plurality of metallization interconnects from the plurality of metallization interconnects 121 of the metallization portion 102, (ii) a second plurality of via interconnects (e.g., 150b) from the plurality of via interconnects 150 and (i) a second plurality of metallization interconnects from the plurality of metallization interconnects 141 of the metallization portion 104. In some implementations, the second inductor 202 may further be defined by a second plurality of solder interconnects from the plurality of solder interconnects 132. The second plurality of solder interconnects from the plurality of solder interconnects 132 may be used to provide electrical paths between the second plurality of metallization interconnects from the plurality of metallization interconnects 121 of the metallization portion 102 and the second plurality of via interconnects (e.g., 150b) from the plurality of via interconnects 150.

In some implementations, the third inductor 203 of the package 100 may be defined by (i) a third plurality of metallization interconnects from the plurality of metallization interconnects 121 of the metallization portion 102, (ii) a third plurality of via interconnects (e.g., 150c) from the plurality of via interconnects 150 and (i) a third plurality of metallization interconnects from the plurality of metallization interconnects 141 of the metallization portion 104. In some implementations, the third inductor 203 may further be defined by a third plurality of solder interconnects from the plurality of solder interconnects 132. The third plurality of solder interconnects from the plurality of solder interconnects 132 may be used to provide electrical paths between the third plurality of metallization interconnects from the plurality of metallization interconnects 121 of the metallization portion 102 and the third plurality of via interconnects (e.g., 150c) from the plurality of via interconnects 150.

The switch device 208 may be an integrated device switch. The switch device 208 may represent the at least one switch device 108. The switch device 208 may include a first switch 218a and a second switch 218b. The switch device 208 may be configured to be electrically coupled to the second inductor 202 and the third inductor 203. The switch 218a may be configured to be electrically coupled to the second inductor 202. The switch 218b may be configured to be electrically coupled to the third inductor 203. The switch device 208 controls whether a current is allowed to pass through the second inductor 202 and/or the third inductor 203.

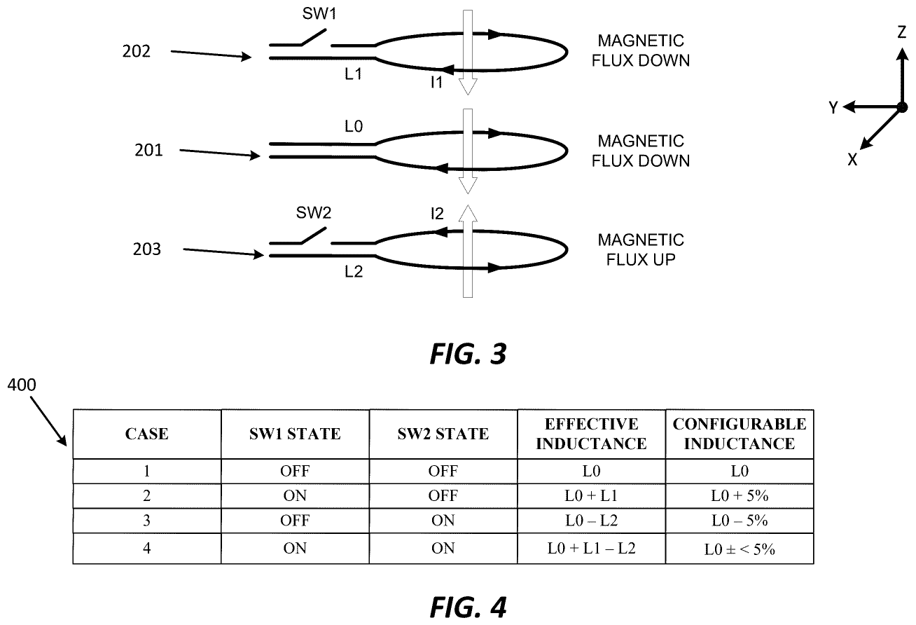

As shown in FIGS. 2-3, a current that passes through the first inductor 201 travels in the A to B direction and a current that passes through the second inductor 202 travels in the A to B direction, while a current that passes through the third inductor 203 is configured to travel in the B to A direction. Turning on the first switch 218a, allows a current to pass through the second inductor 202. Turning off the first switch 218a, prevents a current from passing through the second inductor 202. Since the current that passes through the second inductor 202 travels in approximately the same direction as the current that passes through the first inductor 201, the effective inductance of the first inductor 201 may be increased due to the magnetic flux that is generated by the second inductor 202. The magnetic flux generated by the second inductor 202 is in the same general direction as the magnetic flux of the first inductor 201, which may increase and/or amplify the magnetic flux of the first inductor 201.

Turning on the second switch 218b, allows a current to pass through the third inductor 203. Turning off the second switch 218b, prevents a current from passing through the third inductor 203. Since the current that passes through the third inductor 203 travels in approximately the opposite direction as the current that passes through the first inductor 201, the effective inductance of the first inductor 201 may be decreased due to the magnetic flux that is generated by the third inductor 203. The magnetic flux generated by the third inductor 203 is in the general opposite direction as the magnetic flux of the first inductor 201, which may decrease and/or counter act the magnetic flux of the first inductor 201.

When both the first switch 218a and the second switch 218b are turned on, the effective inductance of the first inductor 201 may be increases or decreased, depending on the specific inductances of second inductor 202 and the third inductor 203.

FIG. 4 illustrates a table 400 of possible scenarios for the operation of a first inductor, a second inductor and a third inductor. The first inductor may be a primary inductor. The first inductor may represent the first inductor 201. The second inductor and/or the third inductor may be secondary inductors. The second inductor may represent the second inductor 202. The third inductor may represent the third inductor 203. The first switch may represent the first switch 218a. The second switch may represent the second switch 218b. As shown in FIG. 4, when both switches are off, the effective inductance of the first inductor 201 is the inductance of the first inductor 201. When the first switch is on and the second switch is off, the effective inductance of the first inductor 201 is the inductance of the first inductor 201 plus the additional inductance caused by the second inductor 202 (which in the example of table 400 is approximately 5% more inductance).

When the first switch is off and the second switch is on, the effective inductance of the first inductor 201 is the inductance of the first inductor 201 minus the inductance caused by the third inductor 203 (which in the example of table 400 is approximately 5% less inductance).

When the first switch is on and the second switch is on, the effective inductance of the first inductor 201 is the inductance of the first inductor 201 plus the inductance caused by the second inductor 202, and minus the inductance caused by the third inductor 203 (which in the example of table 400 is approximately less than 5% more/less inductance).

The change in inductance of the first inductor 201 will vary with the configuration of the second inductor 202 and/or the third inductor 203, as well as the current(s) that passes through the second inductor 202 and/or the third inductor 203. Thus, the 5% difference that is used in the table is merely exemplary. Different implementations may include a different number of inductors and/or inductors with different inductances. The first inductor 201, the second inductor 202 and/or the third inductor 203 may be configured as solenoid inductors.

FIG. 5 illustrates a cross-sectional profile view of an integrated device 501. The integrated device 501 may be a more detailed representation of the integrated device 101 of FIG. 1. The integrated device 501 includes a die substrate portion 502, and a die interconnection portion 504. The die substrate portion 502 includes a die substrate 520 and an active region 522. The active region 522 may include a plurality of logic cells, a plurality of transistors, and/or a plurality of filters. Different implementations may use different types of transistors, such as a field effect transistor (FET), planar FET, finFET, and a gate all around FET. In some implementations, a front end of line (FEOL) process may be used to fabricate the active region 522 of the die substrate 520. The die substrate 520 may include silicon. Thus, the die substrate 520 may be a silicon substrate.

The die interconnection portion 504 includes at least one dielectric layer 540 and a plurality of die interconnects 542. The die interconnection portion 504 is coupled to the die substrate portion 502. The plurality of die interconnects 542 are coupled to the active region 522 of the die substrate portion 502. In some implementations, a back end of line (BEOL) process may be used to fabricate the die interconnection portion 504.

The integrated device 501 includes a plurality of pad interconnects 503 and a passivation layer 506. The plurality of pad interconnects 503 and/or the passivation layer 506 may be coupled to the die interconnection portion 504. The plurality of pad interconnects 503 are coupled to the plurality of die interconnects 542. In some implementations, the plurality of pad interconnects 503 and/or the passivation layer 506 may be considered part of the die interconnection portion 504. The plurality of pad interconnects 503 include a pad interconnect 503a, a pad interconnect 503b, a pad interconnect 503c and a pad interconnect 503d. The plurality of pad interconnects 503 may be coupled to the metallization portion 102. For example, the plurality of pad interconnects 503 may be coupled to and touch the plurality of metallization interconnects 121 of the metallization portion 102.

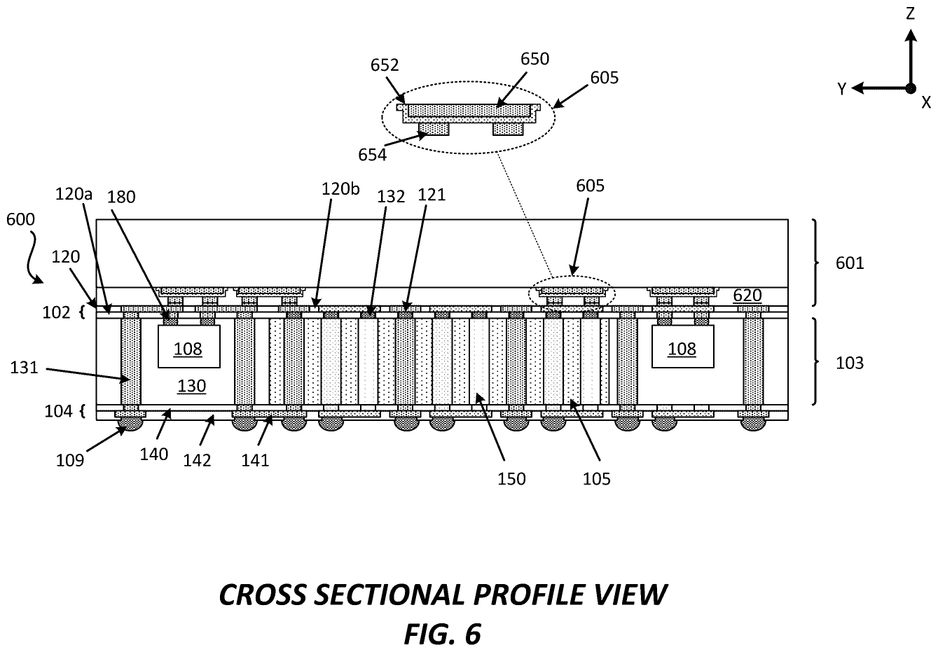

FIG. 6 illustrates a package 600 that includes an integrated device 601, a metallization portion 102, an encapsulated portion 103 and a metallization portion 104. The integrated device 601 may be represented by the integrated device 501. The package 600 is similar to the package 100 of FIG. 1, and thus includes similar components that are arranged and/or configured in a similar manner as described for the package 100. Thus, the arrangement and/or configuration described for the package 100 may also be applicable to the package 600. The package 600 further includes a passive component 605. The passive component 605 may include a capacitor. The passive component 605 may include a metal-insulator-metal (MIM) capacitor. The passive component 605 may include a metal layer 650 (e.g., a first capacitor metal layer), a dielectric layer 652 and a metal layer 654 (e.g., a second capacitor metal layer). In some implementations, the dielectric layer 652 may be a high K dielectric layer. In some implementations, the dielectric layer 652 may be a plasma-enhanced chemical vapor deposition (PECVD) silicon-nitride (SiNx, k~7) or silicon oxide (SiOx: k~4), or a high k dielectric layer, such as atomic layer deposition (ALD) aluminum-oxide (Al2O3: k~9) or zirconium-oxide (ZrO2, k~25), etc.). In some implementations, the metal layer 650 may be a pad interconnect (e.g., 503c) of the integrated device 601. The integrated device 601 may include a dielectric layer 620. The dielectric layer 620 may be different from the dielectric layer 652. The dielectric layer 620 may include polyimide. In some implementations, the passive component 605 may considered part of the integrated device 601. In some implementations, the passive component 605 may be coupled the integrated device 601. The passive component 605 may be coupled to the plurality of metallization interconnects 121 of the metallization portion 102. The passive component 605 may be electrically coupled to the configurable inductor. For example, the passive component 605 may be electrically coupled to the first inductor (e.g., 201). The package 600 may include the at least one switch device 108, the first inductor 201, the second inductor 202 and/or the third inductor 203, as described in at least FIG. 2.

In some implementations, the integrated device 101 and/or the integrated device 601 may be free of an active region and/or free of transistors. In some implementations, the integrated device 101 and/or the integrated device 601 may be free of a die interconnection portion. In some implementations, instead of the integrated device 101 and/or the integrated device 601, a substrate or a base is coupled to and touch the metallization portion 102. The substrate or the base may include silicon and/or glass.

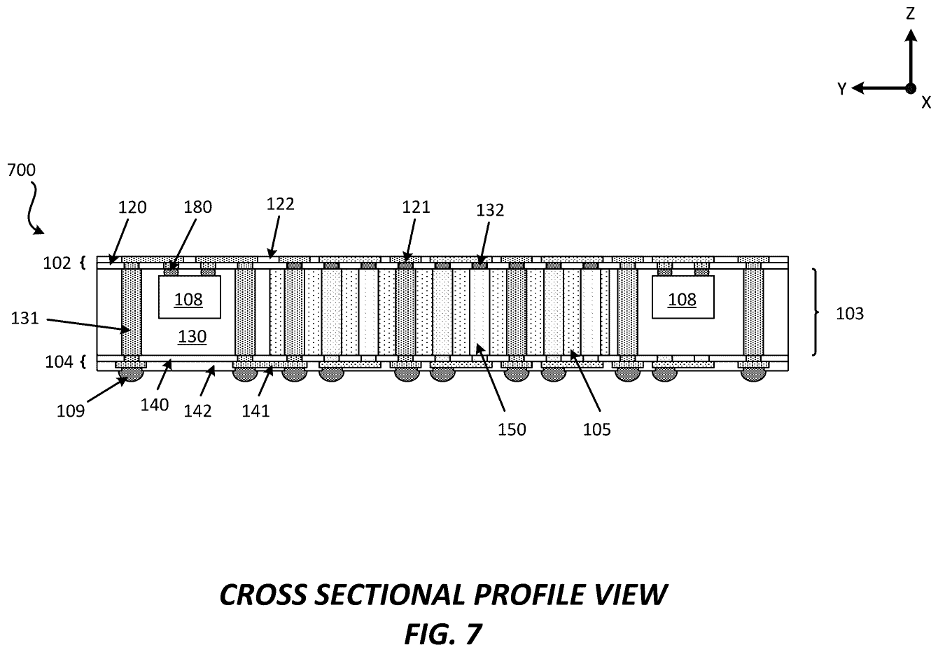

FIG. 7 illustrates a device 700 that includes a metallization portion 102, an encapsulated portion 103 and a metallization portion 104. The encapsulated portion 103 is coupled to the metallization portion 102 and the metallization portion 104. The device 700 may be free of a silicon substrate. For example, no silicon substrate is coupled to and/or touching the metallization portion 102. The encapsulated portion 103 is located between the metallization portion 102 and the metallization portion 104. In some implementations, the metallization portion 102 may be a first metallization portion and the metallization portion 104 may be a second metallization portion. In some implementations, the metallization portion 104 may be a first metallization portion and the metallization portion 102 may be a second metallization portion. The device 700 is similar to the package 100 of FIG. 1, and thus includes similar components that may be arranged and/or configured in a similar manner as described for the package 100. Thus, the arrangement and/or configuration described for the package 100 may also be applicable to the device 700. The package 700 may include the at least one switch device 108, the first inductor 201, the second inductor 202 and/or the third inductor 203, as described in at least FIG. 2. The device 700 provides a configurable inductor with a very compact form factor (e.g., thin device comprising configurable inductor).

A metallization portion (e.g., 102, 104) may include a redistribution portion. A plurality of metallization interconnects (e.g., 121, 141) may include a plurality of redistribution interconnects. A redistribution interconnect may include portions that have a U-shape or V-shape. The terms “U-shape” and “V-shape” shall be interchangeable. The terms “U-shape” and “V-shape” may refer to the side profile shape of the interconnects, metallization interconnects and/or redistribution interconnects. The U-shape interconnect (e.g., U-shape side profile interconnect) and the V-shape interconnect (e.g., V-shape side profile interconnect) may have a top portion and a bottom portion. A bottom portion of a U-shape interconnect (or a V-shape interconnect) may be coupled to a top portion of another U-shape interconnect (or a V-shape interconnect). In some implementations, a process for fabricating redistribution interconnects may form the U-shape interconnect (or the V-shape interconnect). The above description of a metallization portion may apply to other metallization portions described in the disclosure.

An integrated device (e.g., 101) may include a die (e.g., semiconductor bare die). The integrated device may include a power management integrated circuit (PMIC). The integrated device may include an application processor. The integrated device may include a modem. The integrated device may include a radio frequency (RF) device, a passive device, a filter, a capacitor, an inductor, an antenna, a transmitter, a receiver, a gallium arsenide (GaAs) based integrated device, a surface acoustic wave (SAW) filter, a bulk acoustic wave (BAW) filter, a light emitting diode (LED) integrated device, a silicon (Si) based integrated device, a silicon carbide (SiC) based integrated device, a memory, power management processor, and/or combinations thereof. An integrated device may include at least one electronic circuit (e.g., first electronic circuit, second electronic circuit, etc. . . . ). An integrated device may include an input/output (I/O) hub. An integrated device may include transistors. An integrated device may be an example of an electrical component and/or electrical device.

In some implementations, an integrated device may be a chiplet. A chiplet may be fabricated using a process that provides better yields compared to other processes used to fabricate other types of integrated devices, which can lower the overall cost of fabricating a chiplet. Different chiplets may have different sizes and/or shapes. Different chiplets may be configured to provide different functions. Different chiplets may have different interconnect densities (e.g., interconnects with different width and/or spacing). In some implementations, several chiplets may be used to perform the functionalities of one or more chips (e.g., one more integrated devices). As mentioned above, using several chiplets that perform several functions may reduce the overall cost of a package relative to using a single chip to perform all of the functions of a package. In some implementations, one or more of the chiplets and/or one of more of integrated devices (e.g., 101) described in the disclosure may be fabricated using the same technology node or two or more different technology nodes. For example, an integrated device may be fabricated using a first technology node, and a chiplet may be fabricated using a second technology node that is not as advanced as the first technology node. In such an example, the integrated device may include components (e.g., interconnects, transistors) that have a first minimum size, and the chiplet may include components (e.g., interconnects, transistors) that have a second minimum size, where the second minimum size is greater than the first minimum size. In some implementations, a first integrated device and a second integrated device of a package, may be fabricated using the same technology node or different technology nodes. In some implementations, a chiplet and another chiplet of a package, may be fabricated using the same technology node or different technology nodes.

A technology node may refer to a specific fabrication process and/or technology that is used to fabricate an integrated device and/or a chiplet. A technology node may specify the smallest possible size (e.g., minimum size) that can be fabricated (e.g., size of a transistor, width of trace, gap width between two transistors). Different technology nodes may have different yield loss. Different technology nodes may have different costs. Technology nodes that produce components (e.g., trace, transistors) with fine details are more expensive and may have higher yield loss, than a technology node that produces components (e.g., trace, transistors) with details that are less fine. Thus, more advanced technology nodes may be more expensive and may have higher yield loss, than less advanced technology nodes. When all of the functions of a package are implemented in single integrated devices, the same technology node is used to fabricate the entire integrated device, even if some of the functions of the integrated devices do not need to be fabricated using that particular technology node. Thus, the integrated device is locked into one technology node. To optimize the cost of a package, some of the functions can be implemented in different integrated devices and/or chiplets, where different integrated devices and/or chiplets may be fabricated using different technology nodes to reduce overall costs. For example, functions that require the use of the most advanced technology node may be implemented in an integrated device, and functions that can be implemented using a less advanced technology node can be implemented in another integrated device and/or one or more chiplets. One example, would be an integrated device, fabricated using a first technology node (e.g., most advanced technology node), that is configured to provide compute applications, and at least one chiplet, that is fabricated using a second technology node, that is configured to provide other functionalities, where the second technology node is not as costly as the first technology node, and where the second technology node fabricates components with minimum sizes that are greater than the minimum sizes of components fabricated using the first technology node. Examples of compute applications may include high performance computing and/or high performance processing, which may be achieved by fabricating and packing in as many transistors as possible in an integrated device, which is why an integrated device that is configured for compute applications may be fabricated using the most advanced technology node available, while other chiplets may be fabricated using less advanced technology nodes, since those chiplets may not require as many transistors to be fabricated in the chiplets. Thus, the combination of using different technology nodes (which may have different associated yield loss) for different integrated devices and/or chiplets, can reduce the overall cost of a package, compared to using a single integrated device to perform all the functions of the package.

Another advantage of splitting the functions into several integrated devices and/or chiplets, is that it allows improvements in the performance of the package without having to redesign every single integrated device and/or chiplet. For example, if a configuration of a package uses a first integrated device and a first chiplet, it may be possible to improve the performance of the package by changing the design of the first integrated device, while keeping the design of the first chiplet the same. Thus, the first chiplet could be reused with the improved and/or different configured first integrated device. This saves cost by not having to redesign the first chiplet, when packages with improved integrated devices are fabricated.

The package and/or the device (e.g., 100) may be implemented in a radio frequency (RF) package. The RF package may be a radio frequency front end (RFFE) package. A package and/or a device (e.g., 100) may be configured to provide Wireless Fidelity (WiFi) communication and/or cellular communication (e.g., 2G, 3G, 4G, 5G, 6G). The packages and/or devices (e.g., 100) may be configured to support Global System for Mobile (GSM) Communications, Universal Mobile Telecommunications System (UMTS), and/or Long-Term Evolution (LTE). The packages and/or devices (e.g., 100) may be configured to transmit and receive signals having different frequencies and/or communication protocols.

### Exemplary Sequence for Fabricating a Package Comprising Inductors

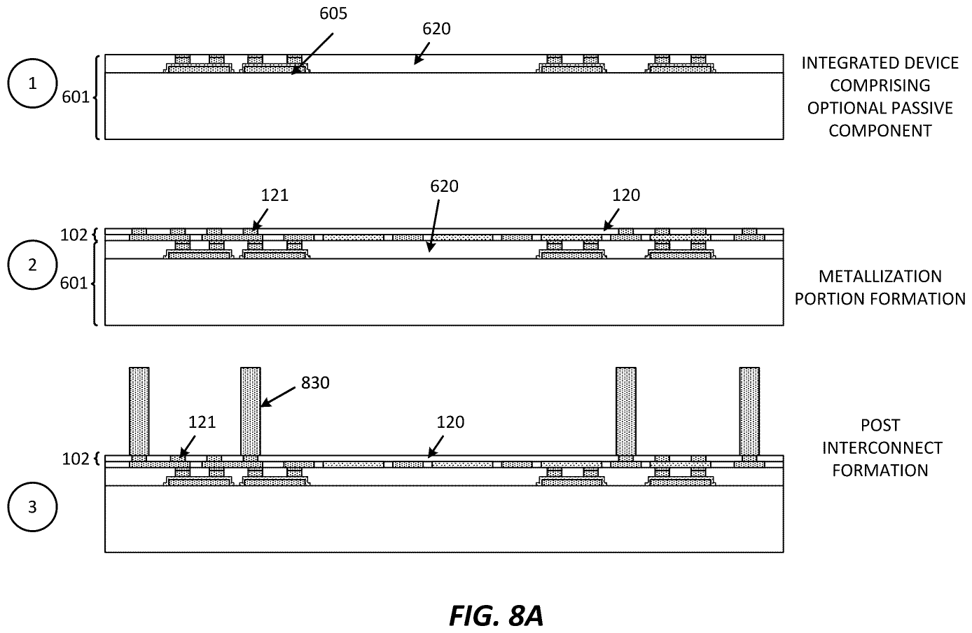

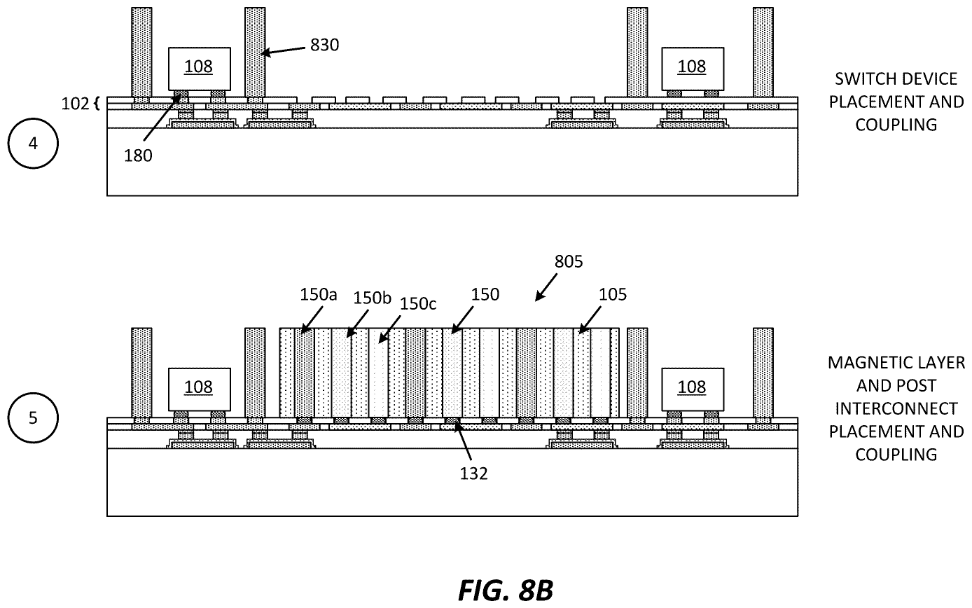

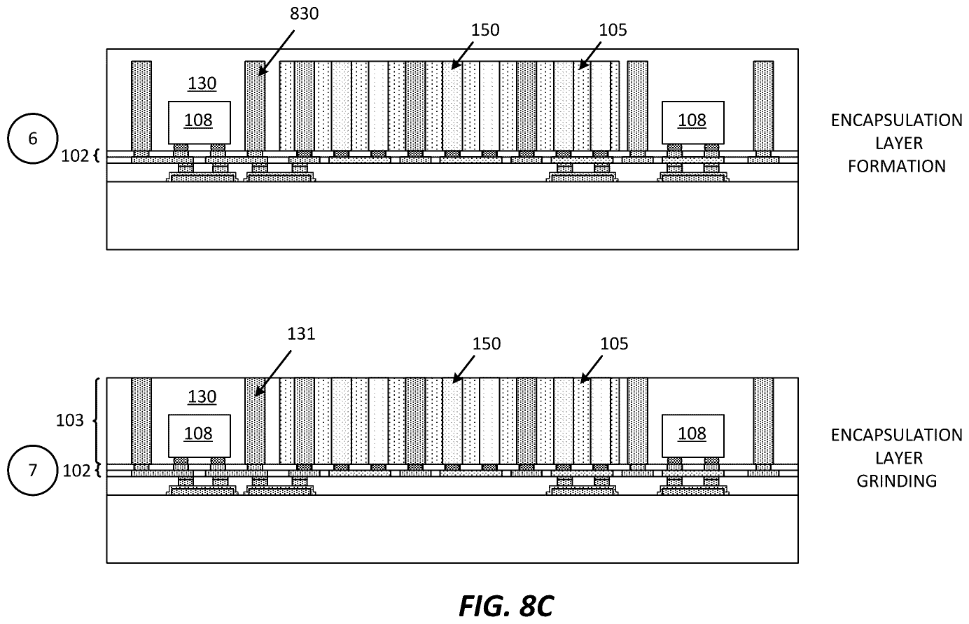

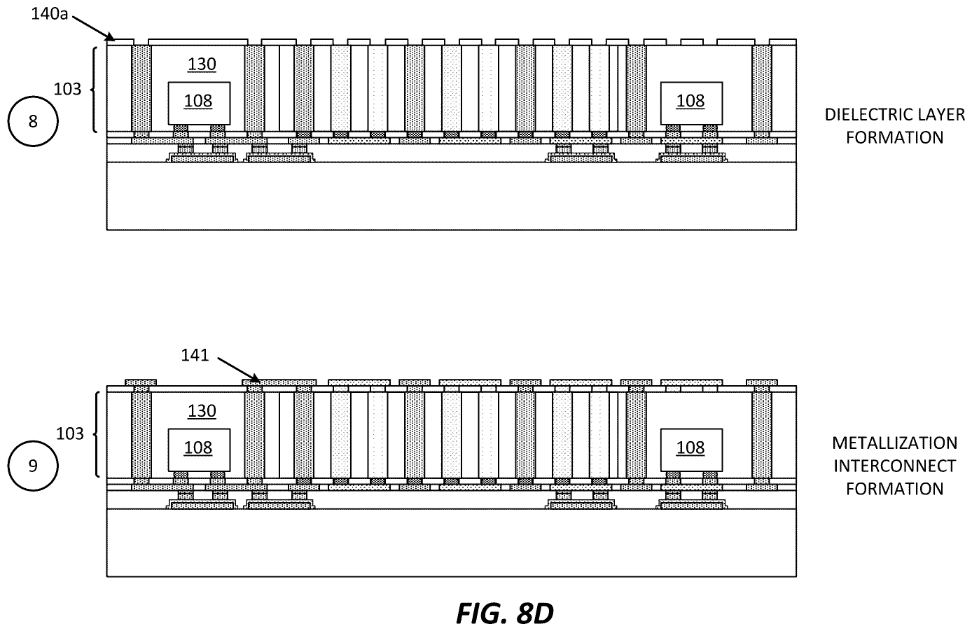

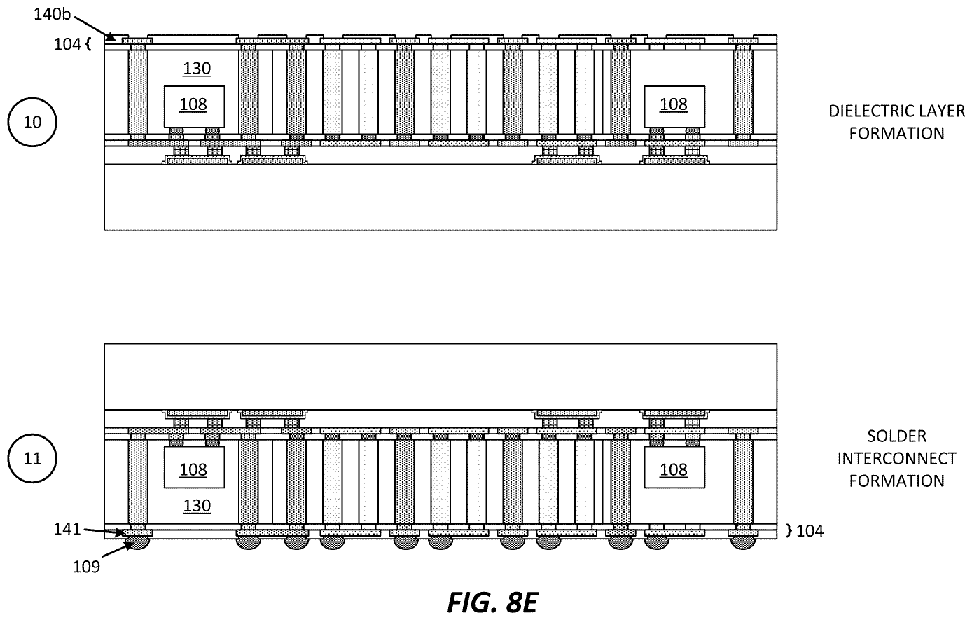

In some implementations, fabricating a package includes several processes. FIGS. 8A-8E illustrate an exemplary sequence for providing or fabricating a package comprising inductors. In some implementations, the sequence of FIGS. 8A-8E may be used to provide or fabricate the package 600. However, the process of FIGS. 8A-8E may be used to fabricate any package or device described in the disclosure.

It should be noted that the sequence of FIGS. 8A-8E may combine one or more stages in order to simplify and/or clarify the sequence for providing or fabricating a package. In some implementations, the order of the processes may be changed or modified. In some implementations, one or more of processes may be replaced or substituted without departing from the scope of the disclosure.

Stage 1, as shown in FIG. 8A, illustrates a state after an integrated device 601 is provided. The integrated device 601 may include a passive component 605 and a dielectric layer 620. The integrated device 601 may be similar to the integrated device 501, and may include components that are arranged in a similar manner as the integrated device 501. The passive component 605 and the dielectric layer 620 may be formed and/or coupled to plurality of pad interconnects (e.g., 503) of the integrated device.

Stage 2 illustrates a state after the metallization portion 102 is formed. The metallization portion 102 may include at least one dielectric layer 120 and a plurality of metallization interconnects 121. The metallization portion 102 is formed and coupled to the integrated device 601. The metallization portion 102 may include a redistribution portion. The plurality of metallization interconnects 121 may include a plurality of redistribution interconnects. A lamination process, a deposition process, a photolithography process, an exposure process, a development process, a plating process, a stripping process and/or an etching process may be used to form the metallization portion 102.

Stage 3 illustrates a state after a plurality of post interconnects 830 are formed and coupled to the metallization portion 102. A lamination process, a deposition process, a photolithography process, an exposure process, a development process, a plating process, a stripping process and/or an etching process may be used to form the plurality of post interconnects 830. The plurality of post interconnects 830 may include copper tall pillars (CuTPs). In some implementations, the plurality of post interconnects 830 (e.g., CuTPs) may have high aspect ratios (e.g., high height to width ratio, height to width ratio of at least 2:1).

Stage 4, as shown in FIG. 8B, illustrates a state after at least one switch device 108 is coupled to the metallization portion 102 through a plurality of solder interconnects 180. The at least one switch device 108 may be placed on the metallization portion 102. A solder reflow process may be used to couple the at least one switch device 108 to the plurality of metallization interconnects 121 of the metallization portion 102.

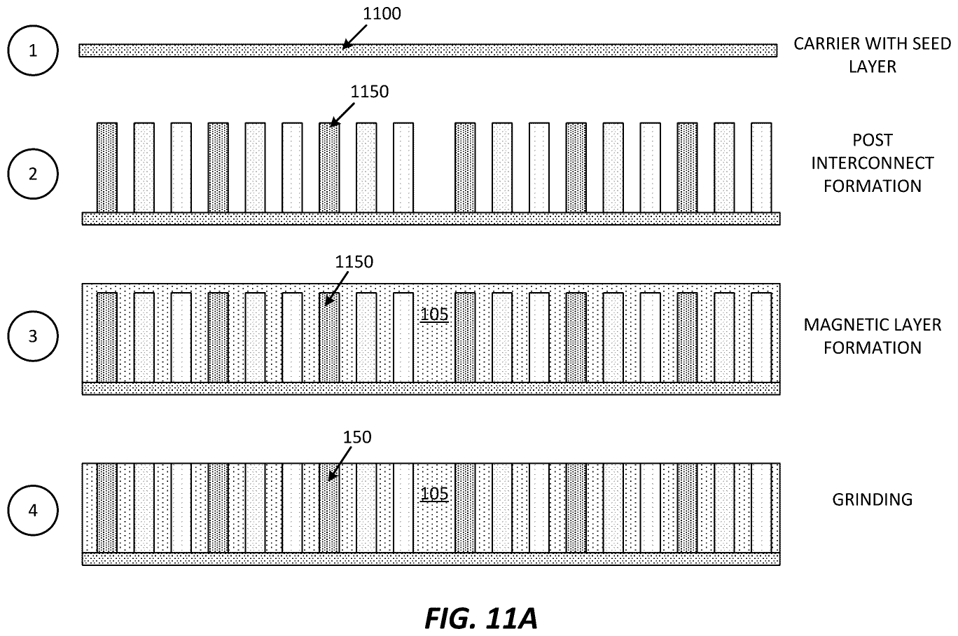

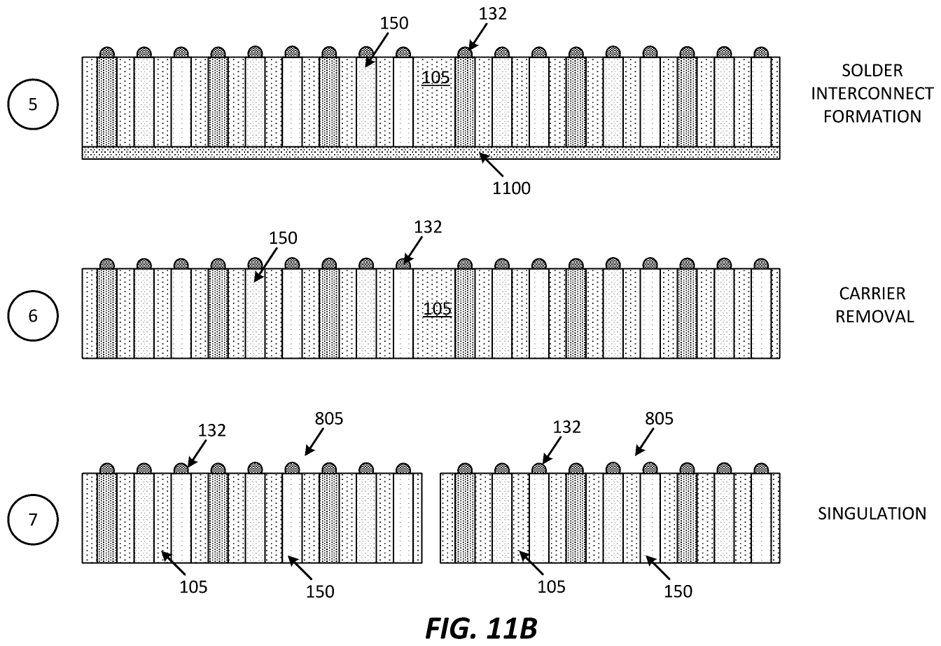

Stage 5 illustrates a state after a structure 805 is placed and coupled to the metallization portion 102 through a plurality of solder interconnects 132. The structure 805 includes a plurality of via interconnects 150 and a magnetic layer 105. The plurality of via interconnects 150 include a plurality of via interconnects 150a, a plurality of via interconnects 150b and a plurality of via interconnects 150c. The plurality of via interconnects 150 are coupled to the plurality of metallization interconnects 121 of the metallization portion 102 through the plurality of solder interconnects 132. FIGS. 11A-11B illustrate and describe an example of a sequence for fabricating a structure that includes a plurality of via interconnects and a magnetic layer.

Stage 6, as shown in FIG. 8C, illustrates a state after an encapsulation layer 130 is formed and coupled to the metallization portion 102. The encapsulation layer 130 may include a mold, a resin, an epoxy and/or a filler. The encapsulation layer 130 may at least partially encapsulate the plurality of post interconnects 830 (e.g., CuTPs), the plurality of via interconnects 150, the at least one switch device 108 and/or the magnetic layer 105. The encapsulation layer 130 may be provided by using a compression and transfer molding process, a sheet molding process, or a liquid molding process. Once the encapsulation layer 130 is formed and encapsulates the plurality of post interconnects 830, the plurality of post interconnects 830 may be considered as the plurality of via interconnects 131.

Stage 7 illustrates a state after a portion of the encapsulation layer 130 is removed. A grinding process may be used to remove and planarize the encapsulation layer 130. In some implementations, a portion of the magnetic layer 105, a portion of the plurality of via interconnects 150 and/or a portion of the plurality of via interconnects 131 may be removed and/or grinded. Stage 7 illustrates an encapsulated portion 103 that is coupled to the metallization portion 102.

Stage 8, as shown in FIG. 8D, illustrates a state after a dielectric layer 140a is formed and coupled to the encapsulation layer 130. The dielectric layer 140a may include a plurality of openings. A lamination process, a deposition process, a laser process, a photolithography process, an exposure process, a development process, and/or a stripping process may be used to form the dielectric layer 140a.

Stage 9 illustrates a state after a plurality of metallization interconnects 141. The plurality of metallization interconnects 141 may be coupled to the plurality of via interconnects 150 and/or the plurality of via interconnects 131. A photolithography process, an exposure process, a development process, a plating process, a stripping process and/or an etching process may be used to form the plurality of metallization interconnects 141.

Stage 10, as shown in FIG. 8E, illustrates a state after a dielectric layer 140b is formed and coupled to the dielectric layer 140a. The dielectric layer 140b may include a plurality of openings. A lamination process, a deposition process, a laser process, a photolithography process, an exposure process, a development process and/or a stripping process may be used to form the dielectric layer 140b.

Stage 11 illustrates a state after a plurality of solder interconnects 109 are coupled to the metallization portion 104. A solder reflow process may be used to couple the plurality of solder interconnects 109 to the plurality of metallization interconnects 141 of the metallization portion 104. Stage 11 may illustrate an example of the package 600.

### Exemplary Flow Diagram of a Method for Fabricating a Package Comprising Inductors

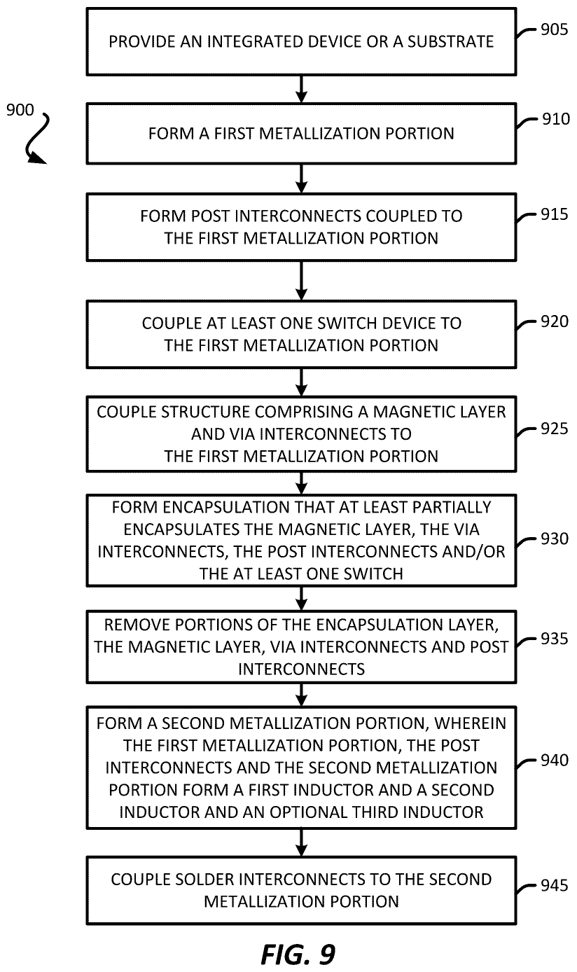

In some implementations, fabricating an integrated device includes several processes. FIG. 9 illustrates an exemplary flow diagram of a method 900 for providing or fabricating a package. In some implementations, the method 900 of FIG. 9 may be used to provide or fabricate the package 600 of FIG. 6. However, the method 900 may be used to provide or fabricate any other packages and/or devices.

It should be noted that the method 900 of FIG. 9 may combine one or more processes in order to simplify and/or clarify the method for providing or fabricating a package. In some implementations, the order of the processes may be changed or modified.

The method provides (at 905) an integrated device or a substrate. The integrated device may include an active region. The integrated device may include a passive component. A substrate may include silicon and/or glass. The substrate may be a base. The substrate may be silicon substrate that is free of an active region and/or free of transistors. Stage 1 of FIG. 8A, illustrates and describes an example of a state after an integrated device 601 is provided. The integrated device 601 may include a passive component 605 and a dielectric layer 620. The integrated device 601 may be similar to the integrated device 501, and may include components that are arranged in a similar manner as the integrated device 501. The passive component 605 and the dielectric layer 620 may be formed and/or coupled to plurality of pad interconnects (e.g., 503) of the integrated device.

The method forms (at 910) a first metallization portion that is coupled to the integrated device or the substrate. Stage 2 of FIG. 8A, illustrates and describes an example of a state after the metallization portion 102 is formed. The metallization portion 102 may include at least one dielectric layer 120 and a plurality of metallization interconnects 121. The metallization portion 102 is formed and coupled to the integrated device 601. The metallization portion 102 may include a redistribution portion. The plurality of metallization interconnects 121 may include a plurality of redistribution interconnects. A lamination process, a deposition process, a photolithography process, an exposure process, a development process, a plating process, a stripping process and/or an etching process may be used to form the metallization portion 102.

The method forms (at 915) a plurality of post interconnects that are coupled to the metallization portion. Stage 3 of FIG. 8A, illustrates and describes an example of a state after a plurality of post interconnects 830 (e.g., CuTPs) are formed and coupled to the metallization portion 102. A lamination process, a deposition process, a photolithography process, an exposure process, a development process, a plating process, a stripping process and/or an etching process may be used to form the plurality of post interconnects 830. In some implementations, the plurality of post interconnects 830 (e.g., CuTPs) may have high aspect ratios (e.g., high height to width ratio, height to width ratio of at least 2:1).

The method couples (at 920) at least one switch (and/or at least one switch device) to the first metallization portion. Stage 4 of FIG. 8B, illustrates and describes an example of a state after at least one switch device 108 is coupled to the metallization portion 102 through a plurality of solder interconnects 180. The at least one switch device 108 may be placed on the metallization portion 102. A solder reflow process may be used to couple the at least one switch device 108 to the plurality of metallization interconnects 121 of the metallization portion 102.

The method couples (at 925) a structure comprising a plurality of via interconnects and a magnetic layer, to the first metallization portion. Stage 5 of FIG. 8B, illustrates and describes an example of a state after a structure 805 is placed and coupled to the metallization portion 102 through a plurality of solder interconnects 132. The structure 805 includes a plurality of via interconnects 150 and a magnetic layer 105. The plurality of via interconnects 150 includes a plurality of via interconnects 150a, a plurality of via interconnects 150b and a plurality of via interconnects 150c. The plurality of via interconnects 150 are coupled to the plurality of metallization interconnects 121 of the metallization portion 102 through the plurality of solder interconnects 132. FIGS. 11A-11B illustrate and describe an example of a sequence for fabricating a structure that includes a plurality of via interconnects and a magnetic layer.

The method forms (at 930) an encapsulation layer that at least partially encapsulates the structure, the at least one switch device and the plurality of post interconnects. Stage 6 of FIG. 8C, illustrates and describes an example of a state after an encapsulation layer 130 is formed and coupled to the metallization portion 102. The encapsulation layer 130 may include a mold, a resin, an epoxy and/or a filler. The encapsulation layer 130 may at least partially encapsulate the plurality of post interconnects 830, the plurality of via interconnects 150, the at least one switch device 108 and/or the magnetic layer 105. The encapsulation layer 130 may be provided by using a compression and transfer molding process, a sheet molding process, or a liquid molding process. Once the encapsulation layer 130 is formed and encapsulates the plurality of post interconnects 830, the plurality of post interconnects 830 may be considered as the plurality of via interconnects 131.

The method forms (at 935) an encapsulation layer that at least partially encapsulates the magnetic layer, the plurality of via interconnects, the plurality of post interconnects and/or the at least one switch. Stage 7 of FIG. 8C, illustrates and describes an example of a state after a portion of the encapsulation layer 130 is removed. A grinding process may be used to remove and planarize the encapsulation layer 130. In some implementations, a portion of the magnetic layer 105, a portion of the plurality of via interconnects 150 and/or a portion of the plurality of via interconnects 131 may be removed and/or grinded. Stage 7 illustrates an encapsulated portion 103 that is coupled to the metallization portion 102.

The method forms (at 940) a second metallization portion that is coupled to the encapsulated portion, wherein the first metallization portion, the encapsulated portion and the second metallization portion form at least a first inductor and a second inductor. Stage 8 of FIG. 8D through stage 10 of FIG. 8E illustrate and describe an example of forming a second metallization portion.

Stage 8 of FIG. 8D, illustrates and describes an example of a state after a dielectric layer 140a is formed and coupled to the encapsulation layer 130. The dielectric layer 140a may include a plurality of openings. A lamination process, a deposition process, a laser process, a photolithography process, an exposure process, a development and/or a stripping process may be used to form the dielectric layer 140a.

Stage 9 of FIG. 8D, illustrates and describes an example of a state after a plurality of metallization interconnects 141. The plurality of metallization interconnects 141 may be coupled to the plurality of via interconnects 150 and/or the plurality of via interconnects 131. A photolithography process, an exposure process, a development process, a plating process, a stripping process and/or an etching process may be used to form the plurality of metallization interconnects 141.

Stage 10 of FIG. 8E, illustrates and describes an example of a state after a dielectric layer 140b is formed and coupled to the dielectric layer 140a. The dielectric layer 140b may include a plurality of openings. A lamination process, a deposition process, a laser process, a photolithography process, an exposure process, a development process may be used to form the dielectric layer 140b.

The method couples (at 945) a plurality of solder interconnects to the second metallization portion. Stage 11 of FIG. 8E, illustrates and describes an example of a state after a plurality of solder interconnects 109 are coupled to the metallization portion 104. A solder reflow process may be used to couple the plurality of solder interconnects 109 to the plurality of metallization interconnects 141 of the metallization portion 104. Stage 11 may illustrate an example of the package 600.

### Exemplary Sequence for Fabricating a Package Comprising Inductors

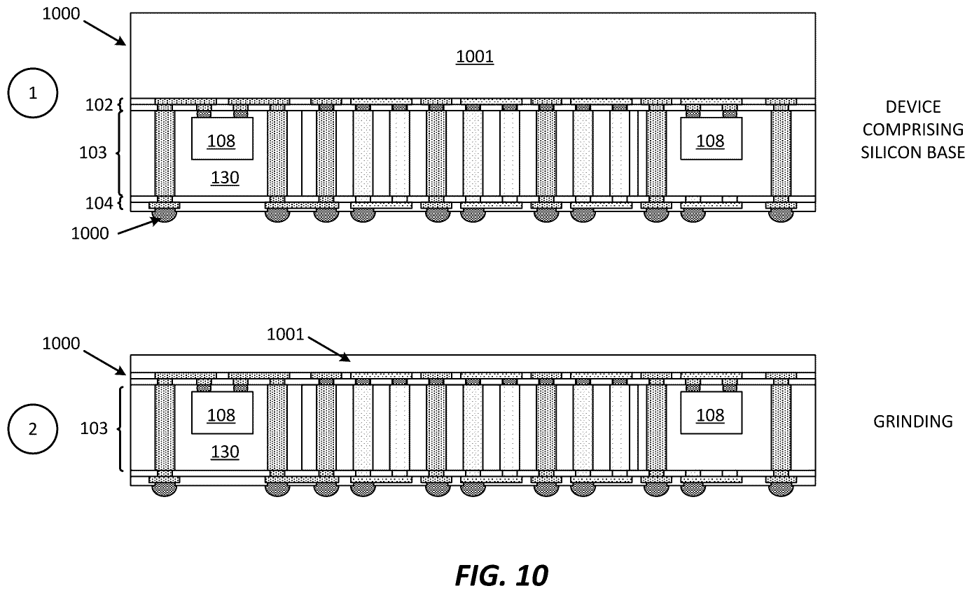

In some implementations, fabricating a package includes several processes. FIG. 10 illustrates an exemplary sequence for providing or fabricating a package comprising inductors. In some implementations, the sequence of FIG. 10 may be used to provide or fabricate the package 1000. However, the process of FIG. 10 may be used to fabricate any package or device described in the disclosure.

It should be noted that the sequence of FIG. 10 may combine one or more stages in order to simplify and/or clarify the sequence for providing or fabricating an integrated device. In some implementations, the order of the processes may be changed or modified. In some implementations, one or more of processes may be replaced or substituted without departing from the scope of the disclosure.

Stage 1 of FIG. 10 illustrates a state after the package 1000 is provided and/or fabricated. In some implementations, the package 1000 may be fabricated using the sequence of FIGS. 8A-8E. The package 1000 is similar to the package 100 and/or the package 600. The device 1000 is similar to the package 100 of FIG. 1 and/or the package 600 of FIG. 6, and thus includes similar components that may be arranged and/or configured in a similar manner as described for the package 100 and/or the package 600. Thus, the arrangement and/or configuration described for the package 100 and/or the package 600 may also be applicable to the device 1000.

However, instead of an integrated device 101 or an integrated device 601, the package 1000 includes a substrate 1001. The substrate 1001 may include silicon and/or a glass. The substrate 1001 may be free of an active region and/or free of transistors. The package 1000 includes the substrate 1001, a metallization portion 102, an encapsulated portion 103, a metallization portion 104 and a plurality of solder interconnects 109. The metallization portion 102 is coupled to the substrate 1001. The encapsulated portion 103 is coupled to the metallization portion 102 and the metallization portion 104. The plurality of solder interconnects 109 are coupled to the metallization portion 104. The package 1000 may include the at least one switch device 108, the first inductor 201, the second inductor 202 and/or the third inductor 203, as described in at least FIG. 2.

Stage 2 illustrates a state after the substrate 1001 has been thinned. A grinding process may be used to remove portions of the substrate 1001. In some implementations, the entire substrate 1001 may be removed and/or grinded off to provide and/or fabricate the device 700 of FIG. 7. The package 1000 may provide a much thinner package and/or a package with a much more compact form factor than the package 100 and/or the package 600.

### Exemplary Sequence for Fabricating a Structure Comprising a Via Interconnects and a Magnetic Layer

In some implementations, fabricating a structure includes several processes. FIGS. 11A-11B illustrate an exemplary sequence for providing or fabricating a structure. In some implementations, the sequence of FIGS. 11A-11B may be used to provide or fabricate the structure 805. However, the process of FIGS. 11A-11B may be used to fabricate any structures described in the disclosure.

It should be noted that the sequence of FIGS. 11A-11B may combine one or more stages in order to simplify and/or clarify the sequence for providing or fabricating a structure comprising via interconnects and a magnetic layer. In some implementations, the order of the processes may be changed or modified. In some implementations, one or more of processes may be replaced or substituted without departing from the scope of the disclosure.

Stage 1, as shown in FIG. 11A, illustrates a state after a carrier 1100 is provided. The carrier 1100 may include a seed layer. The carrier 1100 may include glass and/or silicon.

Stage 2 illustrates a state after a plurality of post interconnects 1150 (e.g., CuTPs) are formed and coupled to the carrier 1100. A lamination process, a deposition process, a photolithography process, an exposure process, a development process, a plating process, a stripping process and/or an etching process may be used to form the plurality of post interconnects 1150. In some implementations, the plurality of post interconnects 1150 (e.g., CuTPs) may have high aspect ratios (e.g., high height to width ratio, height to width ratio of at least 2:1).

Stage 3 illustrates a state after a magnetic layer 105 is provided and formed over the plurality of post interconnects 1150. The magnetic layer 105 may be provided such that the magnetic layer 105 at least partially encapsulates the plurality of post interconnects 1150 (e.g., CuTPs). The magnetic layer 105 may be dispensed and/or deposed over the plurality of post interconnects 1150 (e.g., CuTPs). Once the plurality of post interconnects 1150 (e.g., CuTPs) are encapsulated by the magnetic layer 105, the plurality of post interconnects 1150 may be considered to be the plurality of via interconnects 150.

Stage 4 illustrates a state after a portion of the magnetic layer 105 and a portion of the plurality of via interconnects 150 are removed. A grinding process may be used planarize the magnetic layer 105 and the plurality of via interconnects 150.

Stage 5, as shown in FIG. 11B, illustrates a state after a plurality of solder interconnects 132 are formed and coupled to the plurality of via interconnects 150. A pasting process may be used to provide the plurality of solder interconnects 132. A solder reflow process may be used to couple the plurality of solder interconnects 132 to the plurality of via interconnects 150.

Stage 6 illustrates a state after the carrier 1100 is decoupled from the magnetic layer 105 and the plurality of via interconnects 150. The carrier 1100 may be detached or de-taped from the magnetic layer 105 and the plurality of via interconnects 150.

Stage 7 illustrates a state after singulation which forms the structure 805 that may include the magnetic layer 105, the plurality of via interconnects 150 and the plurality of solder interconnects 132. A saw process may be used for the singulation process.

### Exemplary Flow Diagram of a Method for Fabricating a Structure Comprising a Via Interconnects and a Magnetic Layer

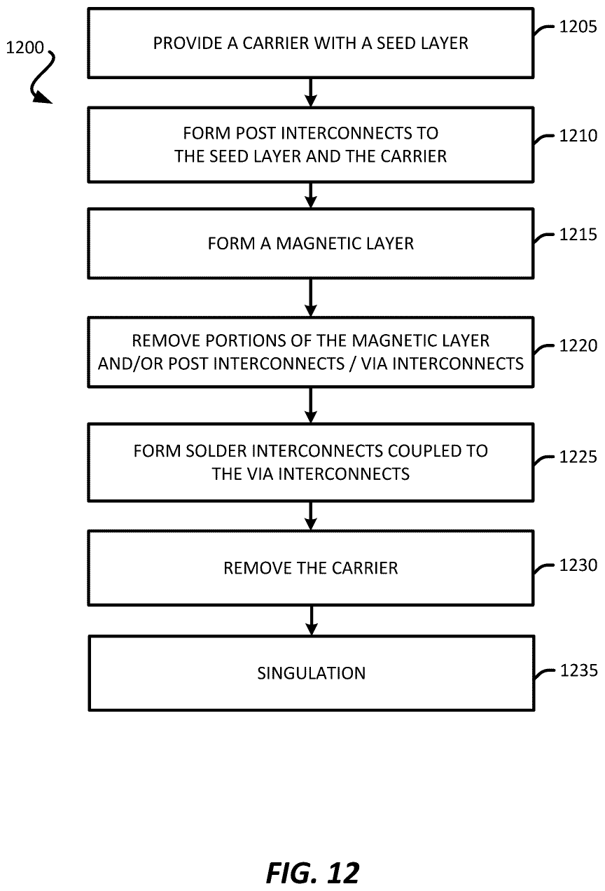

In some implementations, fabricating a structure includes several processes. FIG. 12 illustrates an exemplary flow diagram of a method 1200 for providing or fabricating a structure. In some implementations, the method 1200 of FIG. 12 may be used to provide or fabricate the structure 805. However, the method 1200 may be used to provide or fabricate any other structures that includes a magnetic layer and a plurality of via interconnects.

It should be noted that the method 1200 of FIG. 12 may combine one or more processes in order to simplify and/or clarify the method for providing or fabricating a structure. In some implementations, the order of the processes may be changed or modified.

The method provides (at 1205) a carrier. Stage 1 of FIG. 11A, illustrates and describes an example of a state after a carrier 1100 is provided. The carrier 1100 may include a seed layer. The carrier 1100 may include glass and/or silicon.

The method forms (at 1210) a plurality of post interconnects. Stage 2 of FIG. 11A, illustrates and describes an example of a state after a plurality of post interconnects 1150 are formed and coupled to the carrier 1100. A lamination process, a deposition process, a photolithography process, an exposure process, a development process, a plating process, a stripping process and/or an etching process may be used to form the plurality of post interconnects 1150. In some implementations, the plurality of post interconnects 1150 may have high aspect ratios (e.g., high height to width ratio, height to width ratio of at least 2:1).

The method forms (at 1215) a magnetic layer that at least partially encapsulates the plurality of post interconnects. Stage 3 of FIG. 11A, illustrates and describes an example of a state after a magnetic layer 105 is provided and formed over the plurality of post interconnects 1150. The magnetic layer 105 may be provided such that the magnetic layer 105 at least partially encapsulates the plurality of post interconnects 1150. The magnetic layer 105 may be dispensed and/or deposed over the plurality of post interconnects 1150. Once the plurality of post interconnects 1150 are encapsulated by the magnetic layer 105, the plurality of post interconnects 1150 may be considered to be the plurality of via interconnects 150.

The method removes (at 1220) portions of the magnetic layer and/or portions of the plurality of via interconnects. Stage 4 of FIG. 11A, illustrates and describes an example of a state after a portion of the magnetic layer 105 and a portion of the plurality of via interconnects 150 are removed. A grinding process may be used planarize the magnetic layer 105 and the plurality of via interconnects 150.

The method forms and couples (at 1225) a plurality of solder interconnects to the plurality of via interconnects. Stage 5 of FIG. 11B, illustrates and describes an example of a state after a plurality of solder interconnects 132 are formed and coupled to the plurality of via interconnects 150. A pasting process may be used to provide the plurality of solder interconnects 132. A solder reflow process may be used to couple the plurality of solder interconnects 132 to the plurality of via interconnects 150.

The method removes (at 1230) the carrier. Stage 6 of FIG. 11B, illustrates and describes an example of a state after the carrier 1100 is decoupled from the magnetic layer 105 and the plurality of via interconnects 150. The carrier 1100 may be detached or de-taped from the magnetic layer 105 and the plurality of via interconnects 150.

The method singulates (at 1235). Stage 7 of FIG. 11B, illustrates and describes an example of a state after singulation which forms the structure 805 that may include the magnetic layer 105, the plurality of via interconnects 150 and the plurality of solder interconnects 132. A saw process may be used for the singulation process.

### Exemplary Electronic Devices

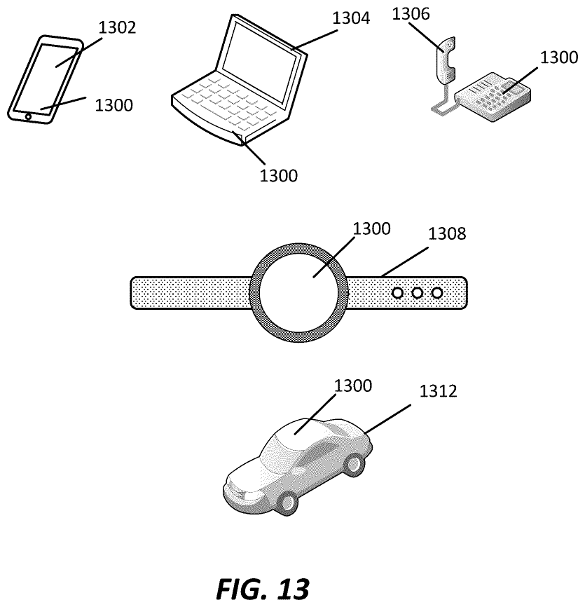

FIG. 13 illustrates various electronic devices that may be integrated with any of the aforementioned device, integrated device, integrated circuit (IC) package, integrated circuit (IC) device, semiconductor device, integrated circuit, die, interposer, package, package-on-package (PoP), System in Package (SiP), or System on Chip (SoC). For example, a mobile phone device 1302, a laptop computer device 1304, a fixed location terminal device 1306, a wearable device 1308, or automotive vehicle 1310 may include a device 1300 as described herein. The device 1300 may be, for example, any of the devices and/or integrated circuit (IC) packages described herein. The devices 1302, 1304, 1306 and 1308 and the vehicle 1310 illustrated in FIG. 13 are merely exemplary. Other electronic devices may also feature the device 1300 including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices (e.g., watches, glasses), Internet of things (IoT) devices, servers, routers, electronic devices implemented in automotive vehicles (e.g., autonomous vehicles), or any other device that stores or retrieves data or computer instructions, or any combination thereof.

One or more of the components, processes, features, and/or functions illustrated in FIGS. 1-7, 8A-8E, 9-10, 11A-11B and 12-13 may be rearranged and/or combined into a single component, process, feature or function or embodied in several components, processes, or functions. Additional elements, components, processes, and/or functions may also be added without departing from the disclosure. It should also be noted FIGS. 1-7, 8A-8E, 9-10, 11A-11B and 12-13 and its corresponding description in the present disclosure is not limited to dies and/or ICs. In some implementations, FIGS. 1-7, 8A-8E, 9-10, 11A-11B and 12-13 and its corresponding description may be used to manufacture, create, provide, and/or produce devices and/or integrated devices. In some implementations, a device may include a die, an integrated device, an integrated passive device (IPD), a die package, an integrated circuit (IC) device, a device package, an integrated circuit (IC) package, a wafer, a semiconductor device, a package-on-package (PoP) device, a heat dissipating device and/or an interposer.

It is noted that the figures in the disclosure may represent actual representations and/or conceptual representations of various parts, components, objects, devices, packages, integrated devices, integrated circuits, and/or transistors. In some instances, the figures may not be to scale. In some instances, for purpose of clarity, not all components and/or parts may be shown. In some instances, the position, the location, the sizes, and/or the shapes of various parts and/or components in the figures may be exemplary. In some implementations, various components and/or parts in the figures may be optional.

The word “exemplary” is used herein to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect coupling (e.g., mechanical coupling) between two objects. For example, if object A physically touches object B, and object B touches object C, then objects A and C may still be considered coupled to one another—even if they do not directly physically touch each other. An object A, that is coupled to an object B, may be coupled to at least part of object B. The term “electrically coupled” may mean that two objects are directly or indirectly coupled together such that an electrical current (e.g., signal, power, ground) may travel between the two objects. Two objects that are electrically coupled may or may not have an electrical current traveling between the two objects. The use of the terms “first”, “second”, “third” and “fourth” (and/or anything above fourth) is arbitrary. Any of the components described may be the first component, the second component, the third component or the fourth component. For example, a component that is referred to a second component, may be the first component, the second component, the third component or the fourth component. The terms “encapsulate”, “encapsulating” and/or any derivation means that the object may partially encapsulate or completely encapsulate another object. The terms “top” and “bottom” are arbitrary. A component that is located on top may be located over a component that is located on a bottom. A top component may be considered a bottom component, and vice versa. As described in the disclosure, a first component that is located “over” a second component may mean that the first component is located above or below the second component, depending on how a bottom or top is arbitrarily defined. In another example, a first component may be located over (e.g., above) a first surface of the second component, and a third component may be located over (e.g., below) a second surface of the second component, where the second surface is opposite to the first surface. It is further noted that the term “over” as used in the present application in the context of one component located over another component, may be used to mean a component that is on another component and/or in another component (e.g., on a surface of a component or embedded in a component). Thus, for example, a first component that is over the second component may mean that (1) the first component is over the second component, but not directly touching the second component, (2) the first component is on (e.g., on a surface of) the second component, and/or (3) the first component is in (e.g., embedded in) the second component. A first component that is located “in” a second component may be partially located in the second component or completely located in the second component. A value that is about X-XX, may mean a value that is between X and XX, inclusive of X and XX. The value(s) between X and XX may be discrete or continuous. The term “about ‘value X’”, or “approximately value X”, as used in the disclosure means within 10 percent of the ‘value X’. For example, a value of about 1 or approximately 1, would mean a value in a range of 0.9-1.1. A “plurality” of components may include all the possible components or only some of the components from all of the possible components. For example, if a device includes ten components, the use of the term “the plurality of components” may refer to all ten components or only some of the components from the ten components.

In some implementations, an interconnect is an element or component of a device or package that allows or facilitates an electrical connection between two points, elements and/or components. In some implementations, an interconnect may include a trace (e.g., trace interconnect), a via (e.g., via interconnect), a pad (e.g., pad interconnect), a pillar, a metallization layer, a redistribution layer, and/or an under bump metallization (UBM) layer/interconnect. In some implementations, an interconnect may include an electrically conductive material that may be configured to provide an electrical path for a signal (e.g., a data signal), ground and/or power. An interconnect may include more than one element or component. An interconnect may be defined by one or more interconnects. An interconnect may include one or more metal layers. An interconnect may be part of a circuit. Different implementations may use different processes and/or sequences for forming the interconnects. In some implementations, a chemical vapor deposition (CVD) process, a physical vapor deposition (PVD) process, a sputtering process, a spray coating, and/or a plating process may be used to form the interconnects.

Also, it is noted that various disclosures contained herein may be described as a process that is depicted as a flowchart, a flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed.

In the following, further examples are described to facilitate the understanding of the invention.

Aspect 1: A device comprising a plurality of via interconnects comprising a first plurality of via interconnects; a second plurality of via interconnects; and a third plurality of via interconnects; at least one switch device; an encapsulation layer at least partially encapsulating the plurality of via interconnects and the at least one switch device; a first metallization portion comprising a plurality of first metallization interconnects, wherein the plurality of first metallization interconnects are coupled to the plurality of via interconnects; and a second metallization portion comprising a plurality of second metallization interconnects, wherein the plurality of second metallization interconnects are coupled to the plurality of via interconnects.

Aspect 2: The device of aspect 1, wherein the plurality of first metallization interconnects comprises a first plurality of first metallization interconnects; a second plurality of first metallization interconnects; and a third plurality of first metallization interconnects, wherein the plurality of second metallization interconnects comprises a first plurality of second metallization interconnects; a second plurality of second metallization interconnects; and a third plurality of second metallization interconnects.

Aspect 3: The device of aspect 2, wherein the first plurality of via interconnects, the first plurality of first metallization interconnects and the first plurality of second metallization interconnects are configured to operate as a first inductor.

Aspect 4: The device of aspect 3, wherein the second plurality of via interconnects, the second plurality of first metallization interconnects and the second plurality of second metallization interconnects are configured to operate as a second inductor.

Aspect 5: The device of aspect 4, wherein the second inductor are electrically coupled to the at least one switch device.

Aspect 6: The device of aspect 4, wherein the third plurality of via interconnects, the third plurality of first metallization interconnects and the third plurality of second metallization interconnects are configured to operate as a third inductor.

Aspect 7: The device of aspect 6, wherein the second inductor and the third inductor are electrically coupled to the at least one switch device.

Aspect 8: The device of aspect 7, wherein the at least one switch device is configured to tune the first inductor by turning on the second inductor and/or the third inductor.

Aspect 9: The device of aspect 8, wherein turning on the second inductor increases an inductance of the first inductor.

Aspect 10: The device of aspect 8, wherein turning on the third inductor decreases an inductance of the first inductor.

Aspect 11: The device of aspect 7, wherein the second inductor is electrically coupled to a first switch device, and wherein the third inductor is electrically coupled to a second switch device.

Aspect 12: The device of aspects 1 through 11, further comprising a magnetic layer that at least partially encapsulates at least some of the via interconnects from the plurality of via interconnects.

Aspect 13: The device of aspects 1 through 12, further comprising at least one passive component coupled to the first metallization portion.

Aspect 14: The device of aspects 1 through 13, further comprising a substrate coupled to the first metallization portion.

Aspect 15: The device of aspect 14, wherein the substrate comprises silicon and/or glass.

Aspect 16: The device of aspects 1 through 15, further comprising an integrated device coupled to the first metallization portion.

Aspect 17: The device of aspect 16, wherein the integrated device comprises an active portion.

Aspect 18: The device of aspect 16, wherein the integrated device comprises a passive component.

Aspect 19: The device of aspect 18, wherein the passive component comprises a metal-insulator-metal (MIM) capacitor.

Aspect 20: The device of aspects 1 through 19, wherein the device comprises a package.

Aspect 21: The device of aspects 1 through 20, wherein the device is from a group consisting one of a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, an internet of things (IoT) device, and a device in an automotive vehicle.

The various features of the disclosure described herein can be implemented in different systems without departing from the disclosure. It should be noted that the foregoing aspects of the disclosure are merely examples and are not to be construed as limiting the disclosure. The description of the aspects of the present disclosure is intended to be illustrative, and not to limit the scope of the claims. As such, the present teachings can be readily applied to other types of apparatuses and many alternatives, modifications, and variations will be apparent to those skilled in the art.

1. A device comprising:
a plurality of via interconnects comprising:
a first plurality of via interconnects;
a second plurality of via interconnects; and
a third plurality of via interconnects;
at least one switch device;
an encapsulation layer at least partially encapsulating the plurality of via interconnects and the at least one switch device;
a first metallization portion comprising a plurality of first metallization interconnects, wherein the plurality of first metallization interconnects are coupled to the plurality of via interconnects; and
a second metallization portion comprising a plurality of second metallization interconnects, wherein the plurality of second metallization interconnects are coupled to the plurality of via interconnects.

2. The device of claim 1,
wherein the plurality of first metallization interconnects comprises:
a first plurality of first metallization interconnects;
a second plurality of first metallization interconnects; and
a third plurality of first metallization interconnects,
wherein the plurality of second metallization interconnects comprises:
a first plurality of second metallization interconnects;
a second plurality of second metallization interconnects; and
a third plurality of second metallization interconnects.

3. The device of claim 2, wherein the first plurality of via interconnects, the first plurality of first metallization interconnects and the first plurality of second metallization interconnects are configured to operate as a first inductor.

4. The device of claim 3, wherein the second plurality of via interconnects, the second plurality of first metallization interconnects and the second plurality of second metallization interconnects are configured to operate as a second inductor.

5. The device of claim 4, wherein the second inductor are electrically coupled to the at least one switch device.

6. The device of claim 4, wherein the third plurality of via interconnects, the third plurality of first metallization interconnects and the third plurality of second metallization interconnects are configured to operate as a third inductor.

7. The device of claim 6, wherein the second inductor and the third inductor are electrically coupled to the at least one switch device.

8. The device of claim 7, wherein the at least one switch device is configured to tune the first inductor by turning on the second inductor and/or the third inductor.

9. The device of claim 8, wherein turning on the second inductor increases an inductance of the first inductor.

10. The device of claim 8, wherein turning on the third inductor decreases an inductance of the first inductor.

11. The device of claim 7,
wherein the second inductor is electrically coupled to a first switch device, and
wherein the third inductor is electrically coupled to a second switch device.

12. The device of claim 1, further comprising a magnetic layer that at least partially encapsulates at least some of the via interconnects from the plurality of via interconnects.

13. The device of claim 1, further comprising at least one passive component coupled to the first metallization portion.

14. The device of claim 1, further comprising a substrate coupled to the first metallization portion.

15. The device of claim 14, wherein the substrate comprises silicon and/or glass.

16. The device of claim 1, further comprising an integrated device coupled to the first metallization portion.

17. The device of claim 16, wherein the integrated device comprises an active portion.

18. The device of claim 16, wherein the integrated device comprises a passive component.

19. The device of claim 18, wherein the passive component comprises a metal-insulator-metal (MIM) capacitor.

20. The device of claim 1, wherein the device comprises a package.
